(19) United States
(12) Patent Application Publication
(10) Pub. No.: US 2014/0326293 A1
(43) Pub. Date: Nov. 6, 2014

(54) METHODS AND APPARATUS FOR SOLAR ENERGY CONCENTRATION AND CONVERSION

(71) Applicant: Ruxiang Jin, Duluth, GA (US)

(72) Inventor: Ruxiang Jin, Duluth, GA (US)

(21) Appl. No.: 13/887,327

(22) Filed: May 5, 2013

(51) Int. Cl. H01L 31/052; F21V 8/00; F24J 2/10

(52) U.S. Cl. CPC H01L 31/0525; F24J 2/10; G02B 6/0096
USPC 136/246; 126/684; 362/551

(57) ABSTRACT

A reflective concentrating optical apparatus capable of efficient solar power collection and conversion is disclosed. A corrugated monolithic reflector or a modified Mersenne optical system with corrugated primary reflector concentrates sunlight with high irradiance uniformity and minimal optical loss, so that an optical fiber bundle or a high efficiency solar cell can be placed near the focal area for efficient light collection or solar-to-electrical power conversion. The solar cell is directly attached onto a phase-transition cooling apparatus comprising a heat pipe and a heat sink to keep the solar cell within a temperature range that enables high solar-to-electrical power conversion efficiency.

### CROSS-REFERENCE TO RELATED APPLICATIONS

This application claims the benefit of the date of provisional patent application No. 61/643,386 (May 7, 2012).

### STATEMENT REGARDING FEDERALLY SPONSORED RESEARCH OR DEVELOPMENT (IF APPLICABLE)

The invention was NOT made by an agency of the United States Government or under a contract with an agency of the United States Government.

### REFERENCE TO SEQUENCE LISTING, A TABLE, OR A COMPUTER PROGRAM LISTING

Not applicable.

### COMPACT DISC APPENDIX (IF APPLICABLE)

Not applicable.

### BACKGROUND OF THE INVENTION

The present invention relates to high concentration reflective optical apparatus. In particular, the present invention relates to high concentration reflective optical systems used in solar energy collection and conversion applications that require high optical system efficiency in generating or utilizing sunlight power, photovoltaic power or solar thermal power.

High concentration optical systems are widely used in various solar systems, including high concentration photovoltaic (HCPV) systems, concentrated solar thermal (CST) systems, and solar illumination systems. In HCPV systems, for example, there are two types of widely used prior-art concentrating optical systems in the market. The first type is the transmissive concentrating system that typically uses Fresnel lens concentrator to focus solar radiation, such as in the system described in U.S. Pat. No. 4,799,778 by Jebens. The second type is the reflective concentrating system that uses light reflectors to focus solar radiation, such as the systems described in U.S. Pat. No. 4,242,580 by Kaplow et al, wherein a Cassegrain telescope configuration is used to concentrate solar radiation.

Some of the key optical system parameters affecting the performance of all concentrating optical systems are concentration ratio, optical system efficiency, scalability, and reliability. In the transmissive concentrating system using Fresnel lenses, there is a trade-off between the concentration ratio and the optical system efficiency, such that it is difficult to achieve concentrations ratios greater than 1000 without suffering efficiency loss because of the energy loss in the refractive optical components. The transmissivity of the manufactured Fresnel lens may also degrade with extended exposure to strong solar radiation.

In the reflective concentrating systems, high concentration ratios (>1000) are relatively easy to achieve while maintaining high optical system efficiency. In the reflective dish concentrating system, a large dish reflector (typically several meters in diameter) is used to focus solar energy onto a solar cell array. Since the amount of solar power collected by the dish is typically of the order of thousands of Watts, active cooling must be used to maintain a working temperature significantly less than 100 degrees Celsius in the solar cell array, possibly affecting the reliability of the HCPV system because continuous power must be applied to the cooling system, and the cooling liquid must be replenished periodically. In a Cassagrain reflective system comprising a plurality of smaller reflectors, the cooling requirement is substantially reduced, but the system is not easily scalable, and accurate alignment of the reflectors with the prisms and the solar cells could be a challenge in controlling the system cost.

In order to maintain the maximum collection efficiency during different times of the day and the year, the concentrating optics are typically mounted on a dual-axis sun tracker that can follow the relative movement of between the sun and the earth with high precision. The sun tracker follows the position of the sun during daytime, so that the optical axis of the concentrator is always in parallel with the direction of the sunlight. In order to reduce the overall system cost, a secondary light collector, such as a light pipe or a prism, is often attached to the front surface of the solar cell to reduce the required tracking accuracy. The light pipe or prism also improves the uniformity of the concentrated solar irradiance on the solar cell surface by redirecting the collected sunlight and quasi-randomly distributing the sunlight through internal reflections. While this approach reduces overall system cost, the disadvantage is that the light pipe or prism will inevitably introduce more optical loss into the system, thereby reducing the overall system efficiency.

The higher concentration ratio results in larger amount of solar energy concentrated onto a small area on the solar cell, whereby increases the cooling requirements because a large portion of the solar energy is converted to heat at the solar cell. In general, passive cooling of the solar cells is preferred because of its reliability. Prior-art passive cooling devices generally use high thermal conductivity metals to remove heat from the solar cell. The apparatus of the present invention uses a passive phase-transition device that significantly improves the cooling efficiency.

The advantages of the present invention will become more apparent with the detailed descriptions in the following sections. The specific details of the embodiments of the methods and apparatus described in the following sections are intended to serve as examples only, and are not intended to limit the scope of the invention.

### BRIEF SUMMARY OF THE INVENTION

The present invention provides a high concentration reflective apparatus, in which sunlight is focused onto a small area near the focal plane using a single corrugated reflector or a plurality of corrugated reflectors. The concentrated solar irradiance on the focus spot is substantially uniform to enable high efficiency solar energy collection and conversion. In one embodiment of the invention, the surface area of the reflector is segmented into a plurality of sub-areas, with each sub-area directing impinging sunlight toward a different position on the solar cell attached to a phase-transition cooler to achieve maximized output power.

In another embodiment, a modified Mersenne telescope arrangement is used to concentrate solar radiation onto a solar cell. The modified Mersenne telescope concentrating apparatus comprises a corrugated primary optical reflector and a parabolic secondary optical reflector. The shapes of the reflecting surfaces of both reflectors are parabolic to the first order, so that all light beams parallel to the reflector axis are directed toward a small area. The corrugated primary reflector directs the collected light beam onto the secondary reflector, and the secondary reflector redirects the concentrated solar beam onto a solar cell. The corrugated primary reflector distributes the concentrated solar irradiance evenly across the surface area of the solar cell. Passive phase-transition cooling systems comprising heat pipes are used to maintain a low temperature of the solar cell.

The solar cell or cell array is mounted onto a phase-transition cooling device comprising preferably a gravitational or capillary heat pipe that does not require active cooling. The heat pipe is attached to a metal heat sink that radiatively and convectively cools the solar cell assembly by exchanging heat with the metal and with the surrounding air.

### BRIEF DESCRIPTION OF THE SEVERAL VIEWS OF THE DRAWINGS

FIG. 1 is a schematic representation of a reflective high concentration photovoltaic system of the present invention. FIG. 1A shows the corrugated reflector. FIG. 1B is a top view of the area segments of the reflector.

FIG. 2 is a schematic representation of several main parts in a module of the present invention.

FIG. 3A is a schematic representation of a parabolic primary reflector with a square cross-section. FIG. 3B is an illustration of a segmented reflector with a square-top cross-section.

FIG. 4 is a schematic representation of the modified Mersenne architecture of the present invention.

### DETAILED DESCRIPTION OF THE INVENTION

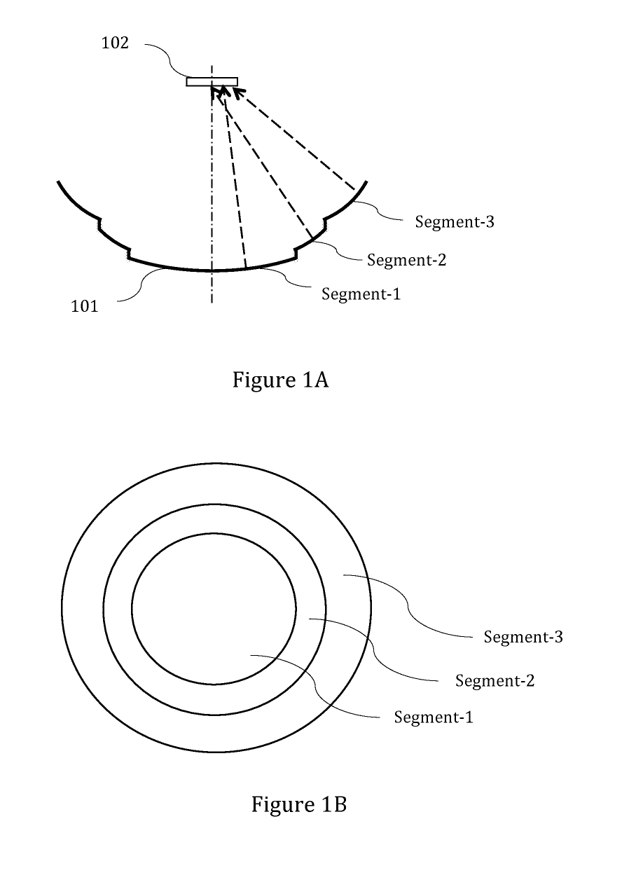

FIG. 1 shows, by way of example, a schematic representation of a reflective high concentration photovoltaic system of the present invention. In FIG. 1A, a modified parabolic reflector 101, preferably made of glass or PMMA (poly(methyl methacrylate)), directs impinging sunlight onto a solar cell 102. The dot-dashed line represents the central axis of the reflector and the solar cell, and the arrows represent the directions of the reflected solar rays.

The solar cell 102 typically comprises III-V semiconductor compounds such as layers of GaAs/InGaAs on germanium substrates. The solar cell 102 serves to absorb radiation energy over the main spectrum of the sun from ultraviolet to infrared wavelengths, and to convert solar power to electrical power with high efficiency. The solar cell 102 can be a single cell or an array of closely packaged cells. The corrugated reflector 101 is typically coated with aluminum or silver to achieve high reflectivity across a wide solar spectral range (typically from 300 to 1800 nm). Commercially available III-V compound solar cell efficiencies routinely exceed 40% in laboratory conditions.

One of the major factors that determine the solar-to-electrical power conversion efficiency is the uniformity of concentrated illumination on the surface area of the solar cell 102. Non-uniform illumination causes local heating that may lower the overall system efficiency or even damage the solar cell. The illumination uniformity is substantially determined by the concentrator optical system design. In the present invention, the surface of the reflector 101 is to the first order parabolic, but is corrugated so that the sunlight striking various parts of the reflector will be directed onto various parts of the solar cell 102 located near the focal plane of the reflector to achieve a substantially uniform illumination on the surface of the solar cell.

Various patterns of reflector-surface segmentation can be embodied to achieve desired illumination pattern on the solar cell surface. In FIG. 1, for example, the surface shape of the reflector is segmented into three areas labeled by Segment-1 to Segment-3, with at least one segment having reflection angles different from that of a perfect parabolic shape to achieve the desired light intensity distribution on the surface of the solar cell. FIG. 1B is a top view of the area segments of the reflector of FIG. 1A. Other segmentation patterns with a larger number of segments can also be easily implemented.

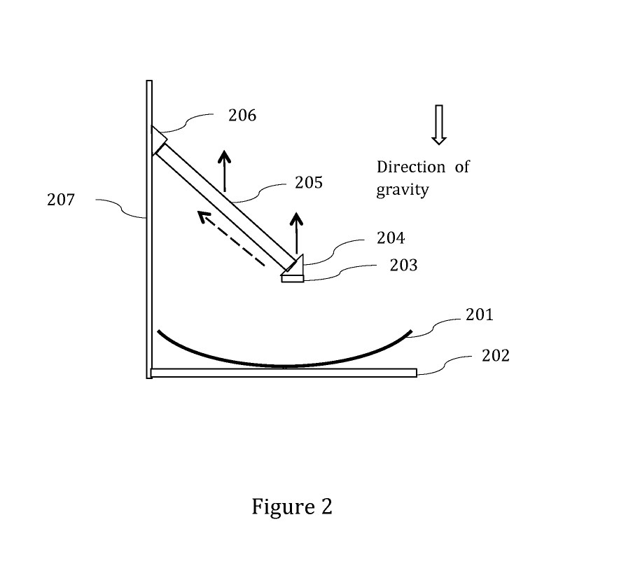

An assembled reflective high concentration module of the present invention is illustrated in FIG. 2. The corrugated reflector 201 mounted on a baseplate 202 directs sunlight onto a solar cell 203 mounted on a heat sink 204. The heat sink 204 preferably comprises a combination of metal, ceramic or other high thermal conductivity material with thermal expansion coefficient similar to that of the solar cell material. The heat sink 204 is connected to another heat sink 206 in good thermal contact with a wall plate 207 through a heat pipe 205 so that the heat generated by concentrated solar radiation is conducted from the solar cell 203 to the wall plate 207. The baseplate 202 and the wall plate 207 preferably comprise high thermal conductivity material such as copper, aluminum or graphene for fast heat removal from the solar cell 203 and dissipation into the surroundings by conduction and radiation.

The heat pipe 205 typically comprises a capillary copper or aluminum tube with a sealed liquid inside, and upon heating the lower end of the heat pipe 205 the liquid evaporates to bring the heat generated at the solar cell 203 to the higher end of the pipe. The heat at the lower end of the heat pipe 205 is generated by the concentrated solar energy on the solar cell 203. The heat is dissipated into the surrounding air at the higher end through the wall plate 207, and the evaporated liquid condenses at the low-temperature high end of the heat pipe 205. The gravitational or capillary effects will then bring the condensed liquid back to the lower end of the heat pipe, and the process repeats itself to keep the solar cell 203 within its optimum operating temperature range.

In general, the heat sinks 204 and 206 and the heat pipe 205 form a thermal conduction path that transfers the heat generated at the solar cell 203 to the wall plate 207, which dissipates the heat into the surrounding air directly by itself, and indirectly through its thermal contact with the baseplate 202. Since the module assembly of FIG. 2 is typically mounted onto a dual-axis sun tracker to ensure maximum photovoltaic generation, the end of the heat pipe 205 that the solar cell 203 is attached to should always be maintained to be the gravitational lower end of the heat pipe 205 during the entire angular movement range of the sun tracker to ensure the most efficient operation of the heat pipe.

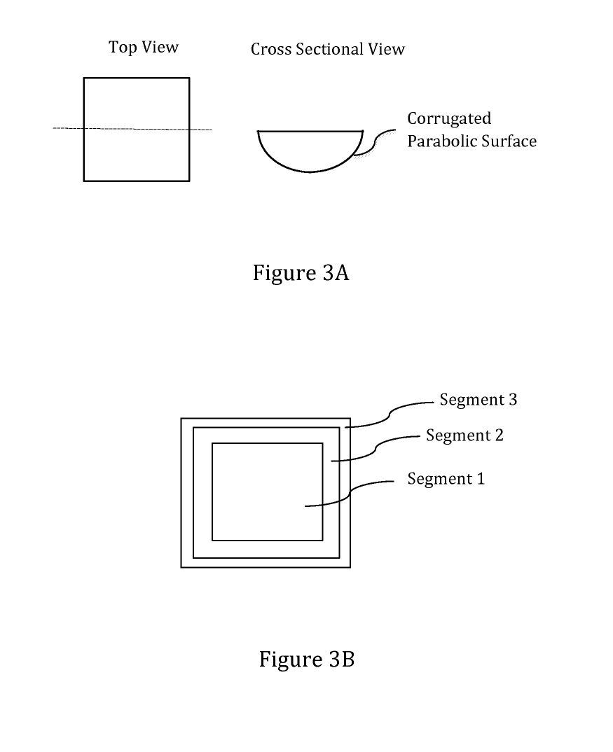

The module in FIG. 2 will generate a level of electrical output power determined primarily by the solar irradiation level and the conversion efficiency of the solar cell 203. In practice, two-dimensional arrays of modules of FIG. 2 are often used to achieve higher levels of output power. In this case, a reflector with a square top is preferred over a reflector with a circular top for more efficient solar energy collection, because a two-dimensional array of non-overlapping circles cannot completely cover a given surface area. FIG. 3A is a schematic representation of a corrugated parabolic primary reflector with a square top cross-section. The square-top reflector is formed by intersecting a three-dimensional paraboloid with four planes parallel to the optical axis of the paraboloid. Such a square-top reflector can also be segmented differently than that depicted in FIG. 1. FIG. 3B is an example of a segmented reflector with a square-top cross-section, in which the different segments of the reflector can direct the solar beam to different portions of a solar cell in a fashion similar to FIG. 1.

In general, more complicated segmentation patterns than those described in FIG. 1 and FIG. 3 are used to divide a reflector surface area into a plurality of sub-areas, each possibly with its own shape, size, and reflection angle. Despite the possible complexity of the segmentation patterns, their fabrication is relatively easy using low-cost injection molding technology for commonly used reflector materials such as PMMA, as long as the segment sizes are larger than a few micrometers. Fabrication of patterns with even smaller dimensions are possible with phase-masking fabrication techniques.

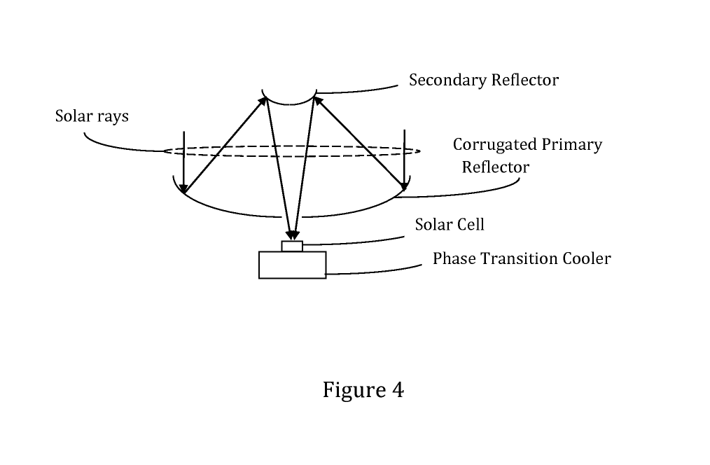

The corrugated reflectors of FIG. 1 can also be used in a two-stage reflective concentration system, such as in a modified Mersenne telescopic architecture comprising a primary- and a secondary reflector. FIG. 4 is a schematic representation of the modified Mersenne architecture of the present invention. Both the primary and secondary reflectors in FIG. 4 are high-reflection coated. The primary reflector focuses the collected light beam onto the secondary reflector, and the secondary reflector redirects the concentrated solar beam onto a solar cell. The arrows in FIG. 4 represent the direction of the sunlight beams. Both the primary- and the secondary reflector in FIG. 4 are parabolic in shape to the first order. The modification of the primary or the secondary reflector surface from that of a perfect parabola in ways similar to that depicted in FIG. 1 helps to distribute solar illumination intensity uniformly across the solar cell area. A passive cooling system is used to maintain a low temperature of the solar cell.

The present invention also solves one of the major design challenges in the optimization of the concentration system performance in very diverse geological locations. One of the most influential parameters that affect the concentrating system design is the average daily direct normal irradiance (DNI), which can vary greatly in different geological locations of the globe. If the concentration system is to be installed in a region with high DNI, for example, the area of the collecting optics should be relatively small to avoid cell output saturation and excessive heating. On the other hand, if the system is to be installed in a region with low DNI, the area of the collecting optics should be relatively large to generated enough electrical power output. Therefore it is desirable to have a scalable optical system that can be optimized easily with respect to different DNI regions, and with minimal changes in the optical system design.

A person with ordinary skills in the art will appreciate that the configuration in FIG. 1 is easily scalable by varying the aperture area of the reflector 101. In the Mersenne telescope configuration presented in FIG. 4, both the primary and the secondary reflectors are parabolic to the first order, and the each reflector can be defined by its diameter and the focal length. Since there is no on-axis spherical aberration, the ratio of the focal lengths of the two reflectors can be designed to be proportional the ratio of the diameters of the reflectors with the output light beam direction from the secondary reflector substantially parallel to the common optical axis of both reflectors, thereby making the system in FIG. 4 scalable for optimized performance in various DNI locations across the globe.

The present invention also reduces or eliminates the need for secondary light pipes that are generally required in prior-art systems to obtain illumination uniformity on the surface of the solar cells, although light pipes such as glass prisms could still be inserted into the present-invention systems in front of the solar cells to reduce the required tracking movement accuracy. The trade-off is that the optical system loss will increase with the introduction of the light pipes or prisms.

In various embodiments of the present invention, the reflector material can be glass, metal, plastic, or other materials, or a combination of several materials having high reflection coating in the 300-1800 nm solar spectrum range. High reflectivity silver alloy coatings can routinely achieve a reflectivity greater than 95% over the said spectrum range on a variety of substrates.

The heat sink and the heat pipe typically comprise copper, aluminum, graphene, or other materials having high thermal conductivity. The evaporative liquid inside the heat pipe is typically water or low boiling-point liquids such as fluorinated ketone. The evaporation and condensation of the liquid forms a thermal loop that efficiently removes the heat from the solar cell, and keeps the solar cell within an optimum operating temperature range. The said thermal loop is completely passive with no external power required.

In some applications, solar thermal energy in the form of hot water is needed together with the photovoltaic generation. In this case, the phase transition cooling of the present invention can be combined with active circulation cooling to achieve for faster heat removal as well as hot water generation, simply by circulating water through heat sink 204 in FIG. 2.

In another embodiment of the present invention, a bundle of optical fibers is placed near the focal plane of the concentrators to replace the solar cell 102 in FIG. 1. Sunlight is coupled into the optical fibers, and the fibers bring the collected sunlight to different locations inside a building for solar lighting applications. In this case, the corrugation of the reflector 101 can be designed to maximize the coupling of sunlight into said fiber bundle.

A person with ordinary skills in the art will appreciate that slight alterations of the apparatus described in the present invention will enable the simultaneous generation and utilization of thermal, electrical, and light energy, or any combinations of the said energy, without departing from the spirit of the present invention.

1. A high concentration reflective optical system comprising:
a corrugated monolithic reflector that is segmented with each segment having reflection angles different from that of an ideal parabola;
a solar cell positioned near the focal plane of the said reflector to receive substantially uniform illumination by said reflector for the maximized conversion of solar energy to electrical energy by the solar cell;
a phase transition cooler attached to said solar cell to form an thermal conduction path from the solar cell to the wall plate or baseplate to remove the heat generated by concentrated solar power at the solar cell.

2. A high concentration reflective optical system comprising:
a modified Mersenne telescope comprising a corrugated monolithic primary reflector of claim 1;
a secondary parabolic reflector that further directs the concentrated solar power onto a solar cell;
a solar cell positioned near the focal plane of said reflectors to receive substantially uniform illumination by the reflectors for the maximized conversion of solar energy to electrical energy by the solar cell;
a phase transition cooler attached to said solar cell to form an thermal conduction path from the solar cell to the wall plate or baseplate to remove the heat generated by concentrated solar power at the solar cell.

3. The reflective system of claim 1 and claim 2, wherein the corrugated reflector has a first-order surface shape that is spherical, hyperbolic, or other pre-defined shape.

4. The reflective system of claim 2, wherein the secondary reflector or both the primary and the secondary reflectors are corrugated and segmented.

5. The reflective system of claim 1 and claim 2, wherein the corrugated reflectors is segmented into N sub-areas, where N can be a very large number limited by the ratio of the segment area divided by the square of the sunlight wavelength.

6. The reflective system of claim 1 and claim 2, wherein the shapes, sizes, and reflection angles of the segmented reflector sub-areas can vary, with each segment directing a different amount of solar energy onto a specific area of the solar cell in order to achieve a desired irradiance distribution.

7. The reflective system of claim 1 and claim 2, wherein a solar cell array instead of a solar cell is place near the focal plane to convert solar power to electrical power.

8. The reflective system of claim 1 and claim 2, wherein optical fibers or light pipes instead of the solar cell and the phase transition cooler are placed near the focal plane to collect directed sunlight.

9. The reflective system of claim 1 and claim 2, wherein a heat collector instead of the solar cell and the phase transition cooler is placed near the focal plane to collect and utilize solar thermal energy.
